(19) United States
(12) Patent Application Publication
(10) Pub. No.: US 2016/0111319 A1
(43) Pub. Date: Apr. 21, 2016

(54) Retainer, Method For Producing Same And Use Thereof

(71) Applicant: CENTROTHERM PHOTOVOLTAICS AG, Blaubeuren (DE)

(72) Inventors: HANS-PETER VOELK, GRIESINGEN (DE); ALEXANDER PIECHULLA, BLAUBEUREN (DE); ULRICH WALK, GOEGGLINGEN (DE); JENS-UWE FUCHS, NEU-ULM (DE); DIETER ZERNICKEL, AMSTETTEN (DE)

(21) Appl. No.: 14/896,530

(22) PCT Filed: Jun. 5, 2014
(86) PCT No.: PCT/DE2014/100190

§ 371 Date: Dec. 7, 2015

(30) Foreign Application Priority Data
Jun. 6, 2013 (DE) 10 2013 105 882.5

(51) Int. Cl. H01L 21/687; H01L 31/18; F28F 13/18; C23C 16/50; C23C 16/32; H01L 21/02; H01L 31/0216

(52) U.S. Cl. CPC H01L 21/68757; H01L 21/02164; H01L 21/0217; H01L 21/0214; H01L 21/02274; H01L 31/18; H01L 31/02167; H01L 31/1876; H01L 21/68771; C23C 16/50; C23C 16/325; F28F 13/18

(57) ABSTRACT

A retainer has a coating composed of silicon carbide, glassy carbon or pyrolytic carbon on its surface. A method for producing the retainer and the use of the retainer in a plasma-driven vapor deposition are also provided.

The invention relates to a retainer, a method for producing the retainer, and the use of same.

In the production of semiconductor components, in particular of silicon solar cells, plasma-driven vapor depositions are often carried out, this being referred to by English speakers in the jargon as plasma-enhanced chemical vapor deposition (PECVD). In this case, the semiconductor substrates to be coated are usually arranged in retainers. So-called boats are regularly used as retainers in PECVD depositions.

In the industrial manufacture of silicon solar cells, silicon solar cell substrates are often arranged in said boats, which in some instances are also referred to as PECVD boats, and are provided with an antireflection layer composed of silicon nitride in the context of a PECVD deposition. Homogeneous antireflection layers are only obtained, however, if the boat used has already been provided with a silicon nitride layer beforehand. Usually, therefore, the boats used are coated with silicon nitride in the context of a so-called silicon nitride precoating before a coating of solar cell substrates arranged in the boats with silicon nitride is carried out. Graphite is usually used as material for the boats. The requirement of the silicon nitride precoating is possibly attributable to the fact that the electrical surface resistances of graphite and the silicon solar cell substrates are too different. However, morphological or chemical reasons, the porosity of the boat material or the grain size constitution thereof may also play a part. The causes have not been definitively clarified at the present time.

Since silicon nitride as dielectric has an electrically insulating effect and the PECVD deposition of silicon nitride on the silicon solar cell substrates necessitates an electrically conductive contact between the boat and the silicon solar cell substrates arranged therein, during the silicon nitride precoating those regions in which the silicon solar cell substrates bear against the boat have to be omitted from the silicon nitride precoating. This is usually realized by arranging silicon substrates in these regions during the silicon nitride precoating, which silicon substrates are usually referred to as dummy wafers and in said regions largely prevent a silicon nitride deposition on holding lugs or sections of the boat surface that are covered by the dummy wafers. In this case, holding lugs should be understood to mean projections on the surfaces of the boats at which the silicon solar cell substrates are supported. The holding lugs make a significant contribution to the electrical contacting since, during silicon nitride depositions, the silicon substrates often do not bear with sufficient area against the boat used.

If oxygen-containing gases are present in a PECVD deposition, for example when nitrous oxide or nitrogen monoxide is used as process gas, then the silicon nitride precoating cannot prevent a decomposition of the boats in those regions which were shielded by the dummy wafers during the silicon nitride precoating. This holds true in the same way for other retainers, such as susceptors used for example in rapid processing installations, so-called rapid thermal processing (RTP) installations. The described decomposition in oxygen-containing process gas atmospheres leads to wear of the retainer used.

Therefore, the present invention is based on the object of providing a retainer which has improved wear resistance in oxygen-containing process gas atmospheres.

This object is achieved by means of a retainer having the features of claim 1.

Furthermore, the invention is based on the object of enabling an outlay-expedient coating of substrates.

This object is achieved by means of a use of the retainer according to the invention as claimed in claim 8.

Furthermore, the invention is based on the object of providing an outlay-expedient method for producing the retainer according to the invention.

This object is achieved by means of a method having the features of claim 11.

Dependent claims respectively relate to advantageous developments.

The retainer according to the invention has a coating composed of silicon carbide, glassy carbon or pyrolytic carbon on its surface.

With retainers coated in this way, it is possible to realize an increased wear resistance in oxygen-containing process gas atmospheres. This is the case particularly for oxygen-containing process gas atmospheres which are formed using nitrous oxide and/or nitrogen monoxide as process gases.

The stated coating materials can be applied, in principle, in any manner known per se. A coating composed of glassy carbon can be applied, for example, by an alcohol bath being admixed with phenolic resin powder and the article that is to be coated being immersed in the resulting solution. Afterward, the article to be coated is heated to a temperature of at least 600° C. This procedure has proved to be worthwhile particularly in the case of articles to be coated which are composed of graphite.

A coating composed of silicon carbide is preferably provided. Silicon carbide is abrasion-proof and resistant to hydrofluoric acid. In most applications, therefore, a post-coating with silicon carbide is required only very rarely. Furthermore, silicon carbide adheres well on graphite, which is a customary material for retainers used in semiconductor technology. Furthermore, it has been found that graphite bodies having a silicon carbide coating have an electrical surface resistance similar to that of silicon solar cell substrates. This appears to have an advantageous effect on the properties of layers deposited on silicon solar cell substrates by means of PECVD methods. However, morphological or chemical reasons or the porosity or the grain size constitution of graphite may also play a part here. It has been found at any rate that the silicon nitride precoating described in the introduction can be omitted in the case of silicon-carbide-coated retainers, particularly in the case of silicon-carbide-coated boats, without the homogeneity of a silicon nitride layer deposited using such a retainer, for example of an antireflection coating, being impaired thereby to a relevant extent. Since silicon carbide is electrically conductive, in addition the dummy wafers described above are not required. In the industrial manufacture of silicon solar cells, the requirement for dummy wafers is a non-negligible cost factor, and so the use of the retainer according to the invention and the associated obviation of the requirement for dummy wafers enable the manufacturing outlay to be reduced.

Silicon carbide or a silicon carbide coating in the present case should be understood to mean that the material used or the coating concerned substantially consists of silicon carbide. A complete purity of the material is not necessary. Impurities, foreign material inclusions at interfaces or the like can be present in amounts that are customary in practice.

If retainers according to the invention are used in silicon nitride depositions, then silicon nitride is also deposited on the retainer used. After a certain number of depositions, silicon nitride parts spall off from the retainer. This can adversely affect the quality of the silicon nitride layer which is deposited on an object arranged in the retainer. For this reason, retainers of silicon nitride deposition installations are usually subjected to etching-back after a certain number of depositions. It has been found that with the use of a retainer according to the invention, the number of possible depositions before a next etching-back step is necessary can be increased compared with retainers known heretofore. This is the case particularly for retainers which have a coating composed of silicon carbide. The higher number of silicon nitride depositions that can be carried out with a retainer until the next etching-back process enables a further reduction of the manufacturing outlay in industrial application, for example in industrial solar cell manufacture.

If the retainer is provided with a coating composed of pyrolytic carbon, then this results in an improved resistance toward oxygen and oxygen radicals compared with a coating with glassy carbon at high temperatures of up to 1100° C. A pyrolytically deposited carbon layer can be combined with pyrolytically deposited carbon by means of an infiltration. Such a combination adheres very well on graphite and is very impermeable. Furthermore, it has a significantly harder surface and is more resistant toward oxygen and oxygen radicals compared with a simple pyrolytically deposited carbon layer. Such retainers accordingly exhibit greater wear resistance toward mechanical stresses and are more resistant toward decomposition in oxygen-containing process environments.

One development provides for the retainer to consist predominantly of graphite or glass. Preferably, it consists of graphite or glass completely, apart from the coating. Said glass can be a quartz glass, in particular. In practice, particularly in the production of semiconductor components, graphite has proved to be particularly worthwhile, for which reason this material is particularly preferred.

The coating is advantageously arranged directly on a core material of the retainer. Precoatings or intermediate coatings can be obviated in this way.

Advantageously, the coating extends over the entire surface of the retainer, such that the increased resistance to wear is present across the entire surface of the retainer. If the retainer is embodied as a graphite boat, then the coating preferably extends over all electrically conductive surface portions of the graphite boat.

In one particularly preferred configuration variant, the coating provided is a silicon carbide coating having a thickness of less than 25 μm. Preferably, the thickness is less than 10 μm and, particularly preferably, the thickness has a maximum value of 10 μm and a minimum value of 1 μm. In the last-mentioned case, the thickness of the silicon carbide coating thus varies in an interval having a lower interval limit of 1 μm and an upper interval limit of 10 μm. It has been found that the wear resistance of the retainer can be increased particularly efficiently in the case of silicon carbide coatings configured in this way.

In one configuration variant, the retainer is embodied as a boat for vapor deposition installations. The vapor deposition installations can be physical vapor deposition (PVD) or chemical vapor deposition (CVD) installations. The boat is preferably suitable for receiving silicon substrates. Particularly preferably, the boat is designed in such a way that it is suitable for use in PECVD installations.

In another embodiment variant, the retainer is embodied as a susceptor for RTP furnaces. RTP furnaces should be understood here to mean furnaces which are suitable for the rapid thermal processing of articles, in particular of semiconductor substrates. RTP furnaces are often heated by means of halogen lamps and enable the article to be heated very rapidly.

The use according to the invention provides for a retainer embodied as a boat for vapor deposition installations to be used as a retainer for substrates in a plasma-driven vapor deposition. In this way, the substrates can be coated in an outlay-expedient manner since the retainer has an increased resistance to wear in an oxygen-containing process gas atmosphere.

The retainer is preferably used for silicon substrates, and particularly preferably used for silicon solar cell substrates. In this way, particularly with the use of boats for which the coating is formed from silicon carbide, in the case of a silicon nitride deposition, a silicon nitride precoating can be dispensed with and use of dummy wafers can be omitted. This substantive matter has already been explained in greater detail above in connection with the retainer. As a result, therefore, silicon substrates, or silicon solar cell substrates, can be coated in a more outlay-expedient manner.

Advantageously, therefore, in the plasma-driven vapor deposition, silicon nitride or silicon oxynitride is deposited on the substrates, preferably silicon nitride. Particularly in a deposition on silicon substrates, or silicon solar cell substrates, a significant reduction of the manufacturing outlay can be brought about in this way.

On account of the increased wear resistance of the retainer in an oxygen-containing process gas atmosphere, the boat can be used particularly advantageously in those PECVD depositions in which an oxygen-containing process gas atmosphere is formed at least temporarily. Particularly in the case of use of graphite boats, this is advantageous since the wear thereof can be reduced in this way. In PECVD silicon oxide depositions, the use of the boat has therefore proved to be advantageous.

According to current knowledge, the advantages afforded by the use according to the invention are established independently of whether the coating is carried out approximately at atmospheric pressure or lower pressure values, independently of whether an ionic or radical coating type is involved and also independently of the plasma frequency used. The use according to the invention has proved to be particularly worthwhile in conjunction with plasma frequencies of less than 400 kHz and especially preferably in conjunction with a plasma frequency of 40 kHz and in conjunction with a plasma frequency of 13.56 kHz or 2.45 GHz.

The method for producing a retainer according to the invention provides for depositing silicon carbide as a coating on a volume material of the retainer by means of a chemical vapor deposition.

In the present case, the term volume material should be understood to mean the material of which the retainer consists before the coating is applied. If the retainer does not consist of a uniform material before the coating is applied, the term volume material thus encompasses all materials of which the retainer consists at this point in time, with the exception of joining parts such as, for example, spacer elements or connecting elements. In particular, possible additional coatings already applied beforehand are included.

By means of the method described, the retainer can be provided with the coating in an outlay-expedient manner. This is the case particularly if the retainer is provided for use in a CVD installation. This is because in this case said CVD installation, which can be embodied for example as a PECVD installation, can be used both for coating the retainer and for coating articles arranged in the retainer later. Said articles can be substrates, for example. Such a coating of the retainer with silicon carbide is significantly more outlay-expedient than an external CVD deposition. Already existing CVD, or PECVD, installations generally only have to be slightly modified in order to enable the silicon carbide deposition. In the case of a PECVD installation already set up for a silicon nitride deposition, by way of example, it is merely necessary additionally to provide a feed device for methane.

Advantageously, the coating is deposited on a volume material which predominantly, preferably completely, consists of graphite or glass. These materials have proved worthwhile in practice and can be used as retainers in many applications, in particular in applications of semiconductor component fabrication. Particularly preferably, a volume material which predominantly or completely consists of graphite is coated, since this material is generally better suited to use in PECVD installations on account of its electrical conductivity.

The deposition of the silicon carbide is preferably carried out by means of a plasma-driven vapor deposition, or in other words by means of a PECVD deposition. For the deposition, advantageously a direct plasma is formed on a surface of the retainer. This has proved to be advantageous particularly if the direct plasma is formed on a graphite surface.

For the deposition of the silicon carbide, a plasma formed using methane and silane can be used. A plasma formed from methane and silane is preferably used.

In one advantageous embodiment variant, the deposited silicon carbide is densified. This can be brought about by means of an ion bombardment, for example, and is particularly preferably realized by means of a plasma. A low-frequency plasma having a plasma frequency of less than 400 kHz has proved to be particularly worthwhile in this context.

The invention is explained in greater detail below with reference to figures. Insofar as appropriate, identically acting elements are provided with identical reference signs herein. The invention is not restricted to the exemplary embodiments illustrated in the figures—not even with regard to functional features. The description above and also the following description of figures contain numerous features which are reproduced in a manner combined as a plurality in part in the dependent claims. However, these features and all the other features disclosed above and in the following description of figures will be considered individually and combined to form expedient further combinations by the person skilled in the art. In particular, these features can be combined in each case individually and in any suitable combination with the retainer and/or the method and/or the use as claimed in the independent claims. In the figures:

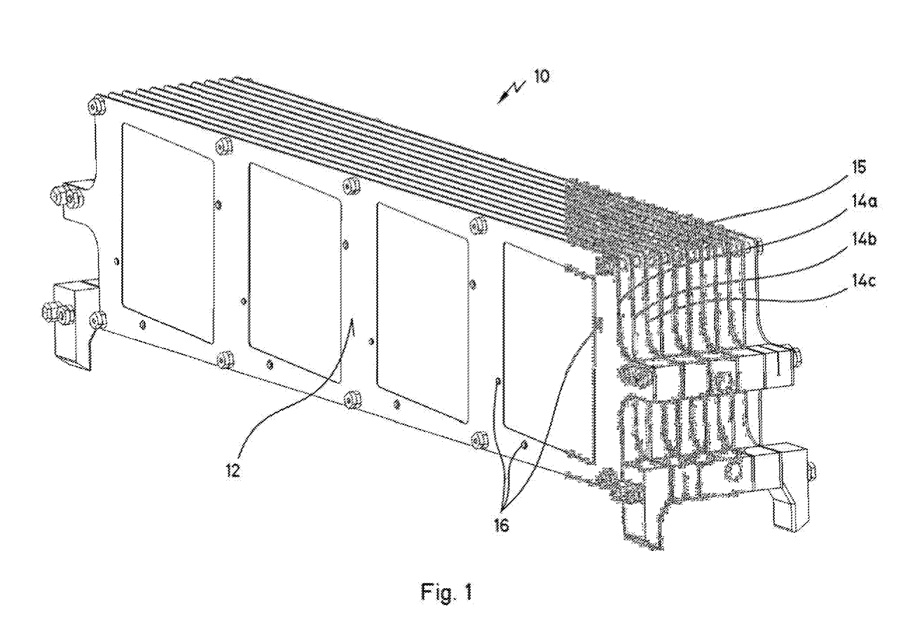

FIG. 1 shows one exemplary embodiment of a retainer embodied as a boat for vapor deposition installations in a schematic illustration

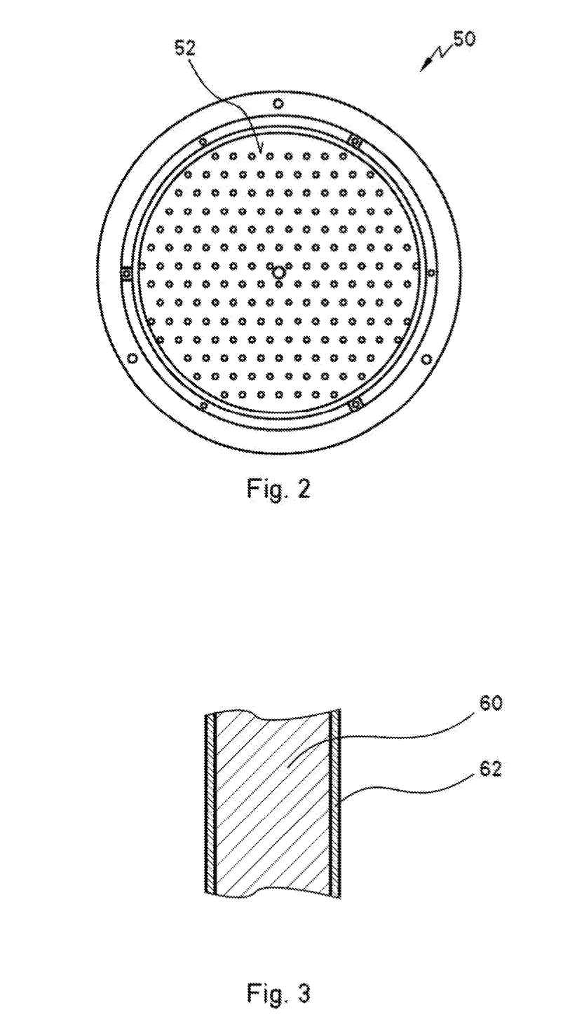

FIG. 2 shows one exemplary embodiment of a retainer embodied as a susceptor for RTP furnaces in a schematic illustration

FIG. 3 shows a schematic partial sectional illustration through the retainer in accordance with FIG. 2 or through the retainer from FIG. 1

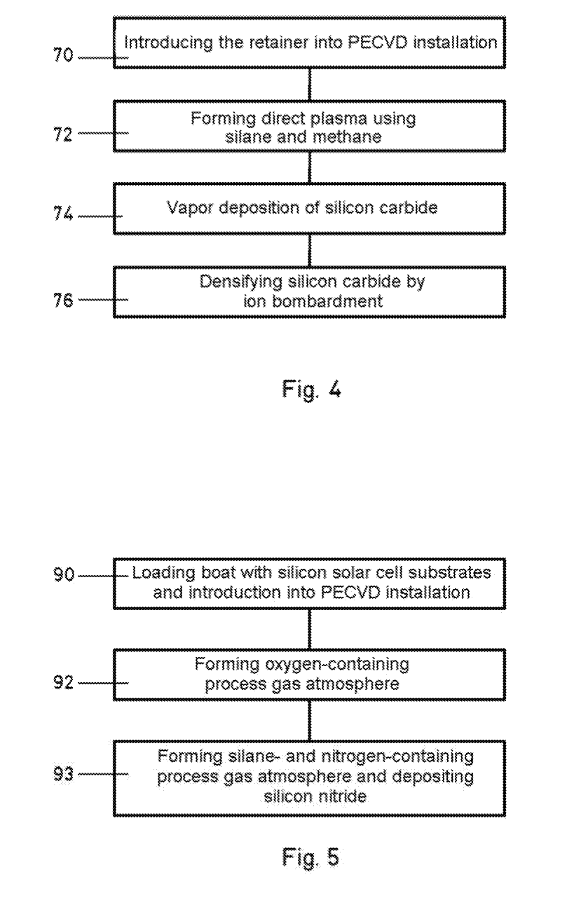

FIG. 4 shows one exemplary embodiment of the method according to the invention

FIG. 5 shows one exemplary embodiment of the use according to the invention.

FIG. 1 illustrates one exemplary embodiment of a retainer embodied as a boat 10 for vapor deposition installations, for a PECVD installation in the present case, in a schematic perspective illustration. The boat 10 is suitable for receiving silicon substrates, and in particular silicon solar cell substrates, and is composed of a plurality of plates 14a, 14b, 14c and further plates in a manner known per se. For receiving silicon substrates, three holding lugs 16 are provided for each of the silicon substrates.

In the exemplary embodiment in FIG. 1, the volume material of the boat 10, apart from insulators 15, consists of graphite on which a coating 12 composed of silicon carbide is arranged directly. Glassy carbon or pyrolytic carbon could also be provided instead of silicon carbide.

Apart from the insulators 15 used as spacers and thus as spacer elements, the coating 12 extends over the entire surface of the boat 10 and has a thickness of between 1 μm and 10 μm.

FIG. 2 shows, in a schematic plan view illustration, one exemplary embodiment of a retainer embodied as a susceptor 50 for RTP furnaces in a schematic illustration. The susceptor 50 has a coating 12 composed of silicon carbide on its surface, said coating extending over the entire surface of the susceptor 52 and having a thickness of between 1 μm and 10 μm. Apart from the coating 52, the susceptor completely consists of graphite or glass. Instead of the coating 52 composed of silicon carbide, the coating can also be formed from glassy carbon or pyrolytic carbon.

The coating 52 is arranged directly on a volume material of the susceptor 50 which consists of graphite or glass in the manner mentioned. This is explained in greater detail below with reference to the illustration in FIG. 3.

FIG. 3 shows a schematic partial sectional illustration through the susceptor 50 from FIG. 2, or through the boat 10 from FIG. 1. In the case of the boat 10 from FIG. 1, FIG. 3 could illustrate for example a partial section through the plate 14a. FIG. 3 shows a volume material 60 provided with a coating 62 on all surfaces. If FIG. 3 is regarded as a partial sectional illustration through the boat 10 from FIG. 1, then the coating 62 constitutes the silicon carbide coating 52 from FIG. 1 and the volume material 60 is graphite. On the other hand, if FIG. 3 is regarded as a partial sectional illustration through FIG. 2, then the coating 62 constitutes the coating 52 composed of silicon carbide and the volume material 60 is graphite or glass. In the exemplary embodiments in FIGS. 1 to 3, the volume material 60 in each case also constitutes the core material of the boat 10 or of the susceptor 50. Precoatings or intermediate coatings are not present.

FIG. 4 shows a basic illustration of one exemplary embodiment of the method according to the invention. In this method, firstly a retainer, for example a boat or a susceptor, is introduced 70 into a PECVD installation. Subsequently, a direct plasma is formed 72 on a surface of the retainer in the PECVD installation using silane and methane. A deposition 74 of silicon carbide is carried out by means of a plasma-driven vapor deposition. Furthermore, the deposited silicon carbide is densified 76 by ion bombardment. The ions used for this purpose are preferably plasma generated by means of a low-frequency plasma.

FIG. 5 illustrates one exemplary embodiment of the use according to the invention in a basic illustration. In this case, a retainer embodied as a boat for vapor deposition installations is loaded with silicon solar cell substrates and introduced 90 into a PECVD installation. In said PECVD installation, an oxygen-containing process gas atmosphere is formed 92, in which, in the present exemplary embodiment, a silicon oxynitride layer is formed on the silicon solar cell substrates. Subsequently, a silane- and nitrogen-containing process gas atmosphere is formed and herein silicon nitride in the form of a silicon-nitride-containing layer is deposited 93 on the silicon solar cell substrates. In the exemplary embodiment illustrated in FIG. 5, the boat used is the boat 10 illustrated in FIG. 1, said boat 10 being provided with a coating 12 composed of silicon carbide and comprising a volume material composed of graphite, such that the boat 10 is protected against premature wear in the oxygen-containing process gas atmosphere by the coating 12 composed of silicon carbide. As explained above, in this embodiment variant it is possible to dispense with a silicon nitride precoating of the boat 10 and likewise with the use of dummy wafers involving high material outlay. The exemplary embodiment in FIG. 5 thus enables an outlay-expedient coating of the silicon solar cell substrates with silicon nitride, for example as an antireflection coating.

### List of Reference Signs

10 boat

12 coating

14a plate

14b plate

14c plate

15 insulator

16 holding lugs

50 susceptor

52 coating

60 volume material

62 coating

70 introducing retainer into PECVD installation

72 forming plasma using silane and methane

74 vapor deposition of silicon carbide

76 densifying silicon carbide by ion bombardment by means of the plasma

90 loading boat with silicon solar cell substrates and introduction into PECVD installation

92 forming oxygen-containing process gas atmosphere and depositing silicon nitride

93 forming silane- and nitrogen-containing process gas atmosphere and depositing silicon nitride

1-16. (canceled)

17. A retainer, comprising:
a core material having a surface; and
a coating disposed directly on said surface of said core material, said coating being composed of silicon carbide, glassy carbon or pyrolytic carbon.

18. The retainer according to claim 17, wherein the retainer is predominantly formed of graphite or glass.

19. The retainer according to claim 17, wherein the retainer is predominantly formed of graphite or glass except for said coating.

20. The retainer according to claim 17, wherein said coating extends entirely over said surface.

21. The retainer according to claim 17, wherein said coating is a silicon carbide coating having a thickness value of:
less than 25 μm; or
less than 10 μm; or
a maximum of 10 μm and a minimum of 1 μm.

22. The retainer according to claim 17, wherein the retainer is constructed as a boat for vapor deposition installations being suitable for receiving silicon substrates.

23. The retainer according to claim 17, wherein the retainer is constructed as a susceptor for rapid thermal processing furnaces.

24. A method for operating a plasma-driven vapor deposition installation, the method comprising the following steps:
providing a retainer constructed as a vapor deposition boat;
placing silicon substrates or silicon solar cell substrates in the boat; and
carrying out a plasma-driven vapor deposition on the substrates in the boat.

25. The method according to claim 24, which further comprises depositing silicon oxide, silicon oxynitride or silicon nitride on the substrates in the plasma-driven vapor deposition step.

26. The method according to claim 24, which further comprises at least temporarily forming an oxygen-containing process gas atmosphere in the plasma-driven vapor deposition step.

27. A method for producing a retainer, the method comprising the following steps:
depositing silicon carbide as a coating on a volume material of the retainer by chemical vapor deposition.

28. The method according to claim 27, wherein the volume material on which the coating is deposited is predominantly or completely formed of graphite or glass.

29. The method according to claim 27, which further comprises carrying out the depositing step by plasma-driven vapor deposition.

30. The method according to claim 29, which further comprises providing the plasma used for the deposition in the form of a direct plasma on a surface of the retainer to be coated.

31. The method according to claim 29, which further comprises using a plasma formed by using methane and silane for the deposition.

32. The method according to claim 27, which further comprises densifying the deposited silicon carbide.

33. The method according to claim 27, which further comprises carrying out the step of densifying the deposited silicon carbide by ion bombardment.

34. The method according to claim 27, which further comprises carrying out the step of densifying the deposited silicon carbide by using a plasma.
